(19) United States
(12) Patent Application Publication
(10) Pub. No.: US 2026/0114313 A1
(43) Pub. Date: Apr. 23, 2026

(54) SEMICONDUCTOR STRUCTURE AND MANUFACTURING METHOD THEREFOR

(71) Applicant: CXMT Corporation, Hefei (CN)

(72) Inventors: Kanyu Cao, Hefei (CN); Ling-Yi Chuang, Hefei (CN); Xiaodong Luo, Hefei (CN)

(73) Assignee: CXMT Corporation, Hefei (CN)

(21) Appl. No.: 19/399,586

(22) Filed: Nov. 24, 2025

Related U.S. Application Data
(63) Continuation of application No. PCT/CN2025/091383, filed on Apr. 27, 2025.

(30) Foreign Application Priority Data
Oct. 17, 2024 (CN) 202411450961.2

(51) Int. Cl. H01L 23/00

(52) U.S. Cl. CPC H10W 72/90; H10W 72/019; H10W 99/00; H10W 72/01931; H10W 72/01953; H10W 72/936; H10W 72/963; H10W 72/967; H10W 80/312; H10W 80/327; H10W 90/792

(57) ABSTRACT

Embodiments of the present disclosure provide a semiconductor structure and a manufacturing method therefor. The structure includes: a first dielectric layer disposed on a substrate, where the first dielectric layer has a first surface away from the substrate; a first bond pad, passing through the first surface and extending to a first depth below the first surface; a second bond pad, passing through the first surface and extending to a second depth below the first surface, where the second depth is less than the first depth; and a second dielectric layer, disposed on the first surface, where a first gap and a second gap are provided in the second dielectric layer, the first gap exposes the top surface of the first bond pad, and the second gap exposes the top surface of the second bond pad.

### CROSS-REFERENCE TO RELATED APPLICATIONS

The present disclosure is a continuation of International Patent Application No. PCT/CN2025/091383, filed on Apr. 27, 2025, which claims priority of the Chinese Patent Application No. 202411450961.2, filed on Oct. 17, 2024 and entitled “SEMICONDUCTOR STRUCTURE AND MANUFACTURING METHOD THEREFOR”. The above-referenced application is incorporated herein by reference in its entirety.

### TECHNICAL FIELD

Embodiments of the present disclosure relate to the field of semiconductor technologies, and in particular, to a semiconductor structure and a manufacturing method therefor.

### BACKGROUND

With continuously rapid growth of a demand for a data capacity, an increase in degree of integration by increasing packaging density to obtain a higher memory capacity has become a target of integrated circuit manufacturing at a current stage. In this foreground, a 3D-IC (three-dimensional integrated circuit) technology is widely employed, to stack and bond wafers with the same function or different functions together. The technology has advantages of high-performance, low-cost, and high-integration.

Hybrid bonding is a process in a 3D packaging technology, and is configured to stack multiple wafers or chips in the vertical direction and implement electrical connection. This technology can significantly increase an integration density of chips, shorten a signal transmission path, reduce power consumption, and further reduce a package volume; and is a technology in fields such as high-performance computing, storage, and mobile devices. High-quality processing of a bonding surface in a bonding procedure directly affects the yield of a bonding process. For example, to ensure that metal pads of the bonding surface have a consistent expansion height in the bonding procedure, a requirement for a surface planarization process is extremely high. Otherwise, a problem of poor bonding exists between mutually bonded surfaces.

### SUMMARY

Embodiments of the present disclosure provide a semiconductor structure with a higher bonding yield and a manufacturing method therefor.

A problem to be solved by technical spirits of the present disclosure is not limited to the above-mentioned problem, and a person skilled in the art clearly understands other unmentioned problems from the following description.

Some embodiments of the present disclosure provide a semiconductor structure, including a substrate; a first dielectric layer disposed on the substrate, where the first dielectric layer has a first surface away from the substrate; a first bond pad, where the first bond pad passes through the first surface and extends to a first depth below the first surface; a second bond pad, where the second bond pad passes through the first surface of the first dielectric layer and extends to a second depth below the first surface, and the second depth is less than the first depth; and a second dielectric layer, where the second dielectric layer is disposed on the first surface, a first gap and a second gap are provided in the second dielectric layer, the first gap exposes the top surface of the first bond pad, and the second gap exposes the top surface of the second bond pad.

In the semiconductor structure provided in some embodiments of the present disclosure, the top surface of the first bond pad and the top surface of the second bond pad are flush with the first surface.

In the semiconductor structure provided in some embodiments of the present disclosure, the surface area of the top surface of the first bond pad exposed to the first gap is less than the surface area of the top surface of the second bond pad exposed to the second gap.

In the semiconductor structure provided in some embodiments of the present disclosure, the first dielectric layer has a first thickness, the second dielectric layer has a second thickness, and the first thickness is greater than the second thickness.

The semiconductor structure provided in some embodiments of the present disclosure further includes a first interconnection structure and a second interconnection structure disposed in the first dielectric layer, the bottom surface of the first bond pad is connected to a first conductive layer through the first interconnection structure, and the bottom surface of the second bond pad is connected to a second conductive layer through the second interconnection structure.

In the semiconductor structure provided in some embodiments of the present disclosure, the top surface of the first conductive layer and the top surface of the second conductive layer are located at different horizontal planes.

Some embodiments of the present disclosure further provide a semiconductor structure, including a substrate; a first dielectric layer disposed on the substrate, where the first dielectric layer has a first surface away from the substrate; a first bond pad, where the first bond pad passes through the first surface and extends to a first depth below the first surface; a second bond pad, where the second bond pad passes through the first surface and extends to a second depth below the first surface, and the second depth is less than the first depth; and a second dielectric layer, where the second dielectric layer is disposed on the first surface, the first bond pad and the second bond pad further extend to the second dielectric layer separately, and extension depths of the first bond pad and the second bond pad in the second dielectric layer are the same.

In the semiconductor structure provided in some embodiments of the present disclosure, the top surface of the first bond pad and the top surface of the second bond pad are exposed to the top surface of the second dielectric layer, and the surface area of the top surface of the first bond pad is less than the surface area of the top surface of the second bond pad.

In the semiconductor structure provided in some embodiments of the present disclosure, the top surface of the first bond pad is flush with the top surface of the second bond pad.

The semiconductor structure provided in some embodiments of the present disclosure further includes a first conductive layer and a second conductive layer disposed in the substrate, the first conductive layer is connected to the bottom surface of the first bond pad and the second conductive layer is connected to the bottom surface of the second bond pad.

Some embodiments of the present disclosure further provide a semiconductor structure, including a first substrate; a first dielectric layer disposed on the first substrate, where the first dielectric layer has a first surface away from the first substrate; a first bond pad, where the first bond pad passes through the first surface and extends to a first depth below the first surface; a second bond pad, where the second bond pad passes through the first surface and extends to a second depth below the first surface, and the second depth is less than the first depth; a second dielectric layer, where the second dielectric layer is disposed on the first surface, the first bond pad and the second bond pad further extend to the second dielectric layer separately, extension depths of the first bond pad and the second bond pad in the second dielectric layer are the same, and the surface area of the top surface of the first bond pad is less than the surface area of the top surface of the second bond pad; a second substrate, where a third dielectric layer is disposed on the second substrate, and the third dielectric layer has a second surface away from the second substrate; a third bond pad, where the third bond pad passes through the second surface and extends to a third depth below the second surface; a fourth bond pad, where the fourth bond pad passes through the second surface and extends to a fourth depth below the second surface, and the fourth depth is less than the third depth; and a fourth dielectric layer, where the fourth dielectric layer is disposed on the second surface, the third bond pad and the fourth bond pad further extend to the fourth dielectric layer separately, extension depths of the third bond pad and the fourth bond pad in the fourth dielectric layer are the same, and the surface area of the top surface of the third bond pad is less than the surface area of the top surface of the fourth bond pad; and the first bond pad is aligned with and bonded to the third bond pad, the second bond pad is aligned with and bonded to the fourth bond pad, and the second dielectric layer is aligned with and bonded to the fourth dielectric layer.

Some embodiments of the present disclosure further provide a manufacturing method for a semiconductor structure, including the following: A substrate is provided. A first dielectric layer is formed on the substrate. The first dielectric layer has a first surface away from the substrate. The first dielectric layer is patterned to form a first trench with a first depth and a second trench with a second depth below the first surface. The second depth is less than the first depth. The first trench and the second trench are filled to respectively form a first bond pad and a second bond pad. A second dielectric layer covering the first surface, the top surface of the first bond pad, and the top surface of the second bond pad is formed. The second dielectric layer is etched, to form a first gap exposing the top surface of the first bond pad and a second gap exposing the top surface of the second bond pad in the second dielectric layer.

In the manufacturing method for a semiconductor structure provided in some embodiments of the present disclosure, steps of the patterning the first dielectric layer to form a first trench with a first depth and a second trench with a second depth below the first surface include: forming a first mask layer on the first surface, patterning the first mask layer to form a first mask pattern in the first mask layer, and performing etching downward along the first mask pattern to form a first initial trench below the first surface; and forming a second mask layer on the first dielectric layer, patterning the second mask layer to form a second mask pattern in the second mask layer, and etching the first dielectric layer along the second mask pattern and the first initial trench to respectively form the second trench and the first trench in the first dielectric layer.

In the manufacturing method for a semiconductor structure provided in some embodiments of the present disclosure, steps of the filling the first trench and the second trench to respectively form a first bond pad and a second bond pad include the following: An initial conductive layer covering the first trench and the second trench is formed. The initial conductive layer also covers the first surface. The initial conductive layer is planarized to respectively form, in the first trench and the second trench, the first bond pad and the second bond pad that are flush with the first surface. The area of the top surface of the first bond pad exposed to the first gap is greater than the area of the top surface of the second bond pad exposed to the second gap.

In the manufacturing method for a semiconductor structure provided in some embodiments of the present disclosure, a first conductive layer and a second conductive layer are formed in the substrate before the first dielectric layer is patterned, and the bottom of the first trench exposes the first conductive layer and the bottom of the second trench exposes the second conductive layer when the first dielectric layer is etched to form the first trench and the second trench.

In the manufacturing method for a semiconductor structure provided in some embodiments of the present disclosure, a first conductive layer and a second conductive layer are formed in the substrate before the first dielectric layer is patterned, a first interconnection trench and a second interconnection trench are further formed when the first dielectric layer is etched to form the first trench and the second trench, the top of the first interconnection trench is connected to the bottom of the first trench, the bottom of the first interconnection trench exposes the first conductive layer, the top of the second interconnection trench is connected to the bottom of the second trench, and the bottom of the second interconnection trench exposes the second conductive layer.

In the manufacturing method for a semiconductor structure provided in some embodiments of the present disclosure, bonding processing is performed after the first gap and the second gap are formed, so that the first bond pad fills the first gap and the second bond pad fills the second gap.

### BRIEF DESCRIPTION OF DRAWINGS

The accompanying drawings herein, which are incorporated in and constitute a part of the specification, illustrate embodiments consistent with the embodiments of the present disclosure, and serve to explain the principles of the embodiments of the present disclosure together with the specification.

FIG. 1 is a schematic cross-sectional view of a semiconductor structure according to an embodiment of the present disclosure;

FIG. 2 is a schematic cross-sectional view of a semiconductor structure according to an embodiment of the present disclosure;

FIG. 3 is a schematic cross-sectional view of a semiconductor structure according to an embodiment of the present disclosure;

FIG. 4 is a schematic cross-sectional view of a semiconductor structure according to an embodiment of the present disclosure;

FIG. 5 is a schematic cross-sectional view of a semiconductor structure according to an embodiment of the present disclosure;

FIG. 6 is a schematic cross-sectional view of a semiconductor structure according to an embodiment of the present disclosure;

FIG. 7 is a schematic cross-sectional view of a semiconductor structure according to an embodiment of the present disclosure;

FIG. 8 is a schematic cross-sectional view of a semiconductor structure according to an embodiment of the present disclosure;

FIG. 9 is a schematic cross-sectional view of a semiconductor structure according to an embodiment of the present disclosure;

FIG. 10 is a schematic cross-sectional view of a semiconductor structure according to an embodiment of the present disclosure;

FIG. 11 is a schematic cross-sectional view of a semiconductor structure according to an embodiment of the present disclosure;

FIG. 12 is a schematic cross-sectional view of a semiconductor structure according to an embodiment of the present disclosure;

FIG. 13 is a schematic cross-sectional view of a semiconductor structure according to an embodiment of the present disclosure;

FIG. 14 is a schematic flowchart of a manufacturing method for a semiconductor structure according to an embodiment of the present disclosure;

FIG. 15 is a schematic cross-sectional view of a semiconductor structure corresponding to a corresponding step in a manufacturing method for a semiconductor structure according to an embodiment of the present disclosure;

FIG. 16 is a schematic cross-sectional view of a semiconductor structure corresponding to a corresponding step in a manufacturing method for a semiconductor structure according to an embodiment of the present disclosure;

FIG. 17 is a schematic cross-sectional view of a semiconductor structure corresponding to a corresponding step in a manufacturing method for a semiconductor structure according to an embodiment of the present disclosure;

FIG. 18 is a schematic cross-sectional view of a semiconductor structure corresponding to a corresponding step in a manufacturing method for a semiconductor structure according to an embodiment of the present disclosure;

FIG. 19 is a schematic cross-sectional view of a semiconductor structure corresponding to a corresponding step in a manufacturing method for a semiconductor structure according to an embodiment of the present disclosure;

FIG. 20 is a schematic cross-sectional view of a semiconductor structure corresponding to a corresponding step in a manufacturing method for a semiconductor structure according to an embodiment of the present disclosure; and

FIG. 21 is a schematic cross-sectional view of a semiconductor structure corresponding to a corresponding step in a manufacturing method for a semiconductor structure according to an embodiment of the present disclosure.

The accompanying drawings have already shown clear embodiments of the present disclosure, which are described in more detail below. These accompanying drawings and text descriptions are not intended to limit the scope of the concept of the embodiments of the present disclosure in any manner, but to describe the concept of the embodiments of the present disclosure for a person skilled in the art with reference to specific embodiments.

### DESCRIPTION OF EMBODIMENTS

The technical solutions in the embodiments of the present disclosure are clearly described below with reference to the accompanying drawings in the embodiments of the present disclosure. It may be understood that specific embodiments described herein are merely intended to explain related disclosures, but are not intended to limit the present disclosure. In addition, it should be further noted that for ease of description, related parts are shown in the accompanying drawings. Unless otherwise defined, all technical and scientific terms adopted in this specification have meanings the same as those commonly understood by a person skilled in the technical field of the present disclosure. The terms adopted in this specification are merely intended to describe the embodiments of the present disclosure, but are not intended to limit the present disclosure. The following descriptions relate to “some embodiments” describing a subset of all possible embodiments. However, it may be understood that “some embodiments” may be the same subset or different subsets of all the possible embodiments, and may be combined with each other when there is no conflict. It should be noted that the term “first\second\third” in the embodiments of the present disclosure is merely intended to distinguish between similar objects, and does not represent specific sorting for the objects. It may be understood that “first\second\third” may be interchanged for a specific sequence or order if allowed, so that the embodiments of the present disclosure described herein can be implemented in a sequence other than those shown or described herein.

When a bonding layer is formed over a semiconductor element by employing a hybrid bonding technology, forming a dielectric layer and forming a bond pad embedded in the dielectric layer are usually included. A procedure of forming the dielectric layer and the bond pad is accompanied by performing a surface planarization process, for example, performing chemical mechanical polishing (CMP) to remove an additional material on the surface of the bonding layer to obtain a flat surface of the bonding layer. The semiconductor element formed with the bonding layer may be prepared to be directly connected to another semiconductor element or a device without employing an intermediate adhesive. Due to mismatch between the thermal expansion of the bond pad and the dielectric layer in the bonding layer, stress mismatch is caused. For example, the bond pad is subjected to tensile stress and the material of the dielectric layer is subjected to compressive stress. This stress unevenness phenomenon may cause deformation and/or warping of the semiconductor element (e.g., a device die, a chip, or a wafer) due to stress concentration. In this case, stress in the bonding layer needs to be continuously reduced and deformation of the semiconductor element needs to be controlled.

To reduce the stress in the bonding layer and alleviate the deformation caused by the mismatch between the thermal expansion of the bond pad and the dielectric layer, in some embodiments, a dummy bond pad (a non-functional bond pad) and an active bond pad (a functional bond pad) are disposed to be relatively evenly distributed into the dielectric layer, to overcome the foregoing stress and deformation by making the bond pad more evenly distributed in the dielectric layer. This is because if two materials are evenly distributed with respect to each other, the expansion of one material may be absorbed or offset by the shrinkage of the other material, thereby reducing or controlling tensile stress and compressive stress. It may be learned that even or approximately even distribution of bond pads (including the dummy bond pad and the active bond pad) in the dielectric layer helps reduce the stress caused by the thermal expansion mismatch and alleviate the deformation. In addition, to ensure that the heights of all bond pads are consistent after thermal expansion, there is a quite high requirement for a surface planarization process, and a surface recess value of each bond pad needs to be precisely controlled in a small window, e.g., a nanometer level. Further, to enable each bond pad to obtain the same surface recess value, it is required that the sizes of the bond pads need to be designed to be the same. In this case, the degree of freedom of design is limited. For example, when bond pads of different areas are required to meet a requirement of a current density, this may be implemented simply by increasing a quantity of bond pads. In addition, the additional dummy bond pad increases the metal density in the bonding layer, and the increase in the metal density also poses an additional challenge to controlling warping of the semiconductor element. Further, an excessively high metal density also causes the area of the dielectric layer to become smaller, wafer bonding strength to become weaker, and increases the risk of slippage in the bonding procedure.

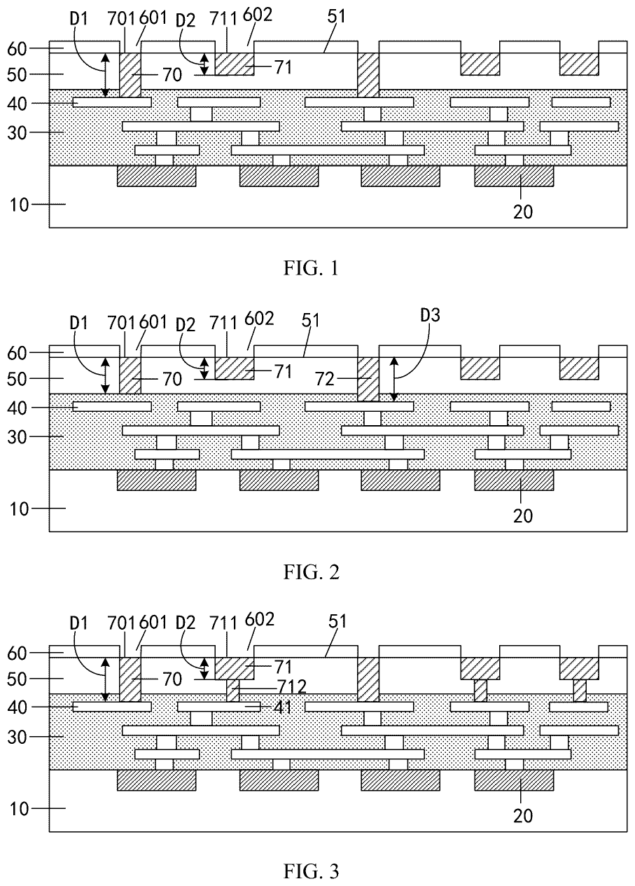

Based at least on the foregoing problems, there is a motivation to adopt a simpler and more efficient bonding layer structure design and process to reduce bonding difficulty and increase a process yield. FIG. 1 is a schematic cross-sectional view of a semiconductor structure according to some embodiments of the present disclosure. The following describes the embodiments of the present disclosure in detail with reference to FIG. 1.

As shown in FIG. 1, the semiconductor structure includes a substrate 10, and a semiconductor device 20 is disposed in the substrate 10. A first dielectric layer 50 is disposed on the substrate 10, and the first dielectric layer 50 has a first surface 51 away from the substrate 10. A first bond pad 70 is disposed in the first dielectric layer 50, passes through the first surface 51 of the first dielectric layer 50 and extends to a lower part of the first surface 51, and has a first depth D1 below the first surface 51. A second bond pad 71 is disposed in the first dielectric layer 50, passes through the first surface 51 of the first dielectric layer 50 and extends to the lower part of the first surface 51, and has a second depth D2 below the first surface 51. The second depth D2 is less than the first depth D1.

The semiconductor structure further includes a second dielectric layer 60. The second dielectric layer 60 is disposed on the first surface 51 of the first dielectric layer 50, a first gap 601 and a second gap 602 are provided in the second dielectric layer 60, the first gap 601 exposes the top surface 701 of the first bond pad 70, and the second gap 602 exposes the top surface 711 of the second bond pad 71. In some embodiments, the top surface 701 of the first bond pad 70 is flush or substantially flush with the top surface 711 of the second bond pad 71.

In some embodiments, the substrate 10 may be a silicon substrate wafer, or may be a substrate wafer having an epitaxial layer (epi-layer), or a silicon on insulator (SOI) substrate wafer. In some embodiments, the substrate 10 may alternatively be a part of a wafer, e.g., a die or a chip.

In some embodiments, the semiconductor device 20 may be a CMOS device, a memory device, and/or another passive device. The memory device may include a volatile memory, a non-volatile memory, or the like, and the volatile memory may include a DRAM and the like. In some embodiments, when being a DRAM memory device, the semiconductor device 20 may be a memory element including one transistor and one capacitor, or may be a set of multiple memory elements.

In some embodiments, the first dielectric layer 50 may be a single dielectric layer formed by one type of dielectric or a composite dielectric layer formed by multiple types of dielectrics. The second dielectric layer 60 may also be a single dielectric layer formed by one type of dielectric or a composite dielectric layer formed by multiple types of dielectrics. In some embodiments, either the first dielectric layer 50 or the second dielectric layer 60 is the single dielectric layer formed by one type of dielectric. In some other embodiments, the first dielectric layer 50 is a multi-layer dielectric layer formed by the multiple types of dielectrics, and the second dielectric layer 60 is the single dielectric layer formed by one type of dielectric. The first dielectric layer 50 and the second dielectric layer 60 may include the same dielectric material, or may include different dielectric materials. In some embodiments, the second dielectric layer 60 is a dielectric layer that can be employed for low temperature direct bonding. In some embodiments, the first dielectric layer 50 includes an oxide, e.g., silicon oxide. In the specification, “silicon oxide” is defined to include a compound containing silicon and oxygen atoms, including SiₓO_{y} representing any and all stoichiometric possibilities of Si, where x and y may be integers or may be non-integers. The second dielectric layer 60 includes an oxide or a nitride, e.g., silicon oxide or silicon nitride (Si₃N₄), silicon carbonitride (SiCN), and silicon oxynitride (SiON). In some embodiments, the first dielectric layer 50 includes SiₓO_{y}, and the second dielectric layer 60 includes SiCN. In some embodiments, the first dielectric layer 50 includes a stacked structure formed by SiₓO_{y} and SiCN, and the second dielectric layer 60 includes SiCN.

In the foregoing embodiment, the first bond pad 70 and the second bond pad 71 are bond pads subsequently employed for direct bonding in the semiconductor structure, e.g., copper-containing metal pads or other bond pads that may be employed for direct bonding at a low temperature. The first bond pad 70 may be an active bond pad, and is electrically connected to at least the semiconductor device 20. The second bond pad 71 may be a dummy bond pad, and is disposed in the first dielectric layer 50 and does not establish an electrical connection to the semiconductor device 20. In some embodiments, in the first dielectric layer 50 of a unit area, the density of first bond pads 70 is different from that of second bond pads 71, and the quantity of the first bond pads 70 may be greater than the quantity of the second bond pads 71. In some embodiments, the quantity of the first bond pads 70 may alternatively be less than the quantity of the second bond pads 71.

In the foregoing embodiment, the first gap 601 and the second gap 602 may expose completely the top surface 701 of the first bond pad 70 and the top surface 711 of the second bond pad 71, respectively. In some embodiments, the first gap 601 and the second gap 602 may alternatively expose parts of the top surfaces of the first bond pad 70 and the second bond pad 71.

Still referring to FIG. 1, in some embodiments, the semiconductor structure further includes an interlayer insulating layer 30 disposed on the substrate 10. Multi-layer metal wiring connecting the semiconductor device 20 is disposed in the interlayer insulating layer 30. The multi-layer metal wiring includes a first conductive layer 40. The first bond pad 70 is electrically connected to the semiconductor device 20 through the first conductive layer 40. In some embodiments, the first conductive layer 40 may be the topmost metal wiring in the multi-layer metal wiring, or may be a metal wiring next to the topmost metal wiring. In some embodiments, the bottom surface of the first bond pad 70 is directly connected to the first conductive layer 40.

Some embodiments of the present disclosure further provide a semiconductor structure. As shown in FIG. 2, FIG. 2 is a schematic cross-sectional view of a semiconductor structure according to some embodiments of the present disclosure. Different from the embodiment shown in FIG. 1, both a first bond pad 70 and a second bond pad 71 are dummy bond pads, that is, neither the first bond pad 70 nor the second bond pad 71 is electrically connected to a semiconductor device 20. The first bond pad 70 extends to a first depth D1 below a first surface 51, the second bond pad 71 extends to a second depth D2 below the first surface 51, and the first depth D1 is greater than the second depth D2. In this case, an active bond pad 72 electrically connected to the semiconductor device 20 is further disposed in a first dielectric layer 50, and the active bond pad 72 extends to a depth D3 below the first surface 51. The depth D3 is greater than the first depth D1 and the second depth D2.

Some embodiments of the present disclosure further provide a semiconductor structure. As shown in FIG. 3, FIG. 3 is a schematic cross-sectional view of a semiconductor structure according to some embodiments of the present disclosure. An interlayer insulating layer 30 further includes a second conductive layer 41. Different from the semiconductor structure in the embodiment shown in FIG. 1, a first bond pad 70 and a second bond pad 71 in the semiconductor structure in these embodiments are active bond pads electrically connected to the semiconductor device 20. In these embodiments, the second conductive layer 41 may be a metal wiring layer in the same layer as a first conductive layer 40. To be specific, both the first conductive layer 40 and the second conductive layer 41 are the topmost metal wiring in multi-layer metal wiring. In this case, the top surfaces of the first conductive layer 40 and the second conductive layer 40 are in the same horizontal plane. In these embodiments, the bottom surface of the first bond pad 70 is directly connected to the first conductive layer 40, and the bottom surface of the second bond pad 71 is connected to the second conductive layer 41 through a second interconnection structure 712.

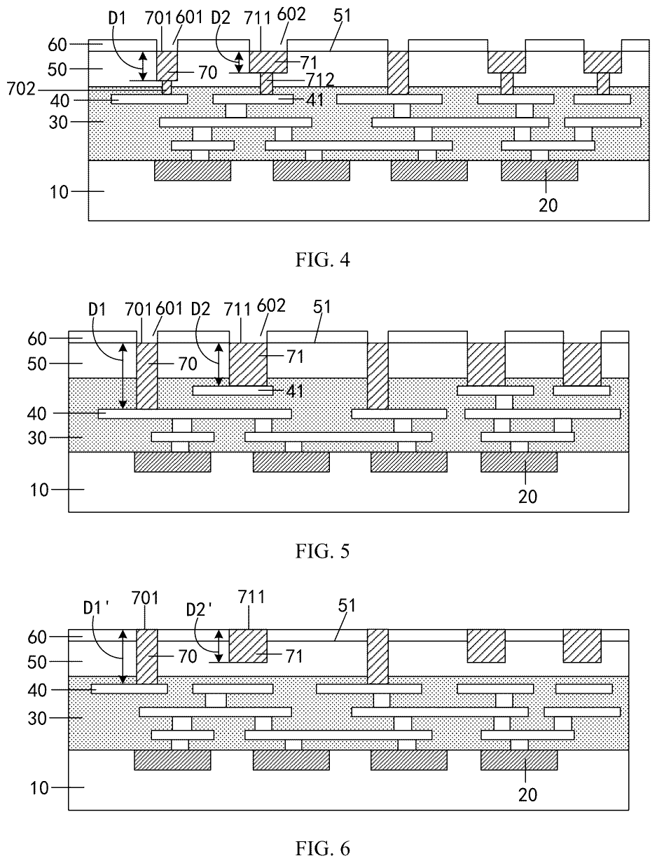

Some embodiments of the present disclosure further provide a semiconductor structure. As shown in FIG. 4, FIG. 4 is a schematic cross-sectional view of a semiconductor structure according to some embodiments of the present disclosure. Different from the embodiment shown in FIG. 3, a first bond pad 70 in the semiconductor structure in these embodiments is electrically connected to a first conductive layer 40 through a first interconnection structure 702.

In the embodiments shown in FIG. 3 and FIG. 4, the first interconnection structure 702 and the second interconnection structure 712 may adopt the same conductive material as the first bond pad 70 and the second bond pad 71, for example, all are copper-containing metals.

In some embodiments, the first interconnection structure 702 may be formed in the interlayer insulating layer 30, and the second interconnection structure 701 is formed in both the first dielectric layer 50 and the interlayer insulating layer 30.

Some embodiments of the present disclosure further provide a semiconductor structure. As shown in FIG. 5, FIG. 5 is a schematic cross-sectional view of a semiconductor structure according to some embodiments of the present disclosure. In these embodiments, multi-layer metal wiring includes a first conductive layer 40 and a second conductive layer 41, and the first conductive layer 40 and the second conductive layer 41 are metal wiring at different layers. In other words, the top surfaces of the first conductive layer 40 and the second conductive layer 41 are located at different horizontal planes. For example, the first conductive layer 40 is the second topmost metal wiring, and the second conductive layer 41 is the topmost metal wiring. In these embodiments, a first bond pad 70 is connected to the first conductive layer 40, and a second bond pad 71 is connected to the second conductive layer 41. The bottom surface of the first bond pad 70 may be directly or indirectly connected to the first conductive layer 40, and the bottom surface of the second bond pad 71 may also be directly or indirectly connected to the second conductive layer 41. When the bottom surface of the first bond pad 70 is directly connected to the first conductive layer 40, the first bond pad 70 has a part extending to an interlayer insulating layer 30. A first depth D1 of the first bond pad 70 below a first surface 51 includes a depth extending in a first dielectric layer 50 and a depth extending in the interlayer insulating layer 30. When the bottom surface of the second bond pad 71 is directly connected to the second conductive layer 41, the second bond pad 71 may also have a part extending to the interlayer insulating layer 30. In this case, a second depth D2 of the second bond pad 71 below the first surface 51 includes a depth extending in the first dielectric layer 50 and a depth extending in the interlayer insulating layer 30. In some embodiments, the second bond pad 71 may be directly connected to the second conductive layer 41 by extending through the first dielectric layer 50. A specific connection manner is not limited to the structure shown in FIG. 5. In some other embodiments, the first bond pad 70 and the second bond pad 71 may further implement electrical connection to the first conductive layer 40 and the second conductive layer 41 through the first interconnection structure 702 and the second interconnection structure 712 shown in FIG. 4.

In the semiconductor structures provided in the foregoing embodiments, the top surfaces of the first bond pad 70 and the second bond pad 71 are respectively exposed to a first gap 601 and a second gap 602 that are located in a second dielectric layer 60. In other words, for the first bond pad 70 and the second bond pad 71, surface recess values of the first bond pad 70 and the second bond pad 71 relative to the second dielectric layer 60 are uniformly determined by the thickness of the second dielectric layer 60 itself. The surface recess values of the first bond pad 70 and the second bond pad 71 may become the same by controlling the thickness of the second dielectric layer 60. Therefore, it is possible to avoid employing a high-precision surface planarization process to control the surface recess values of the first bond pad 70 and the second bond pad 71.

Still referring to FIG. 1 to FIG. 5, in some other embodiments, the top surface 701 of the first bond pad 70 and the top surface 711 of the second bond pad 71 are flush or substantially flush with the first surface 51 of the first dielectric layer 50. In this embodiment of the present disclosure, the top surface 701 of the first bond pad 70 and the top surface 711 of the second bond pad 71 are controlled to be flush or substantially flush with the first surface 51 of the first dielectric layer 50 in advance, to ensure that the first bond pad 70 and the second bond pad 71 have the same surface recess value relative to the second dielectric layer 60.

Still referring to FIG. 1 to FIG. 5, in some embodiments, the surface area of the top surface 701 of the first bond pad 70 exposed to the first gap 601 is less than the surface area of the top surface 711 of the second bond pad 71 exposed to the second gap 602. In these embodiments, the first gap 601 completely exposes the top surface 701 of the first bond pad 70, and the second gap 602 completely exposes the top surface 711 of the second bond pad 71. To be specific, the size of the top surface 701 of the first bond pad 70 on the horizontal plane is less than the size of the top surface 711 of the second bond pad 71 on the horizontal plane. In these embodiments, the first bond pad 70 and the second bond pad 71 that have different surface areas are disposed, and the first bond pad 70 and the second bond pad 71 are further controlled to have different extension depths. By controlling a relationship between the first bond pad 70 and the second bond pad 71, the same expansion amount can be obtained by the first bond pad 70 and the second bond pad 71 in a subsequent bonding processing procedure. The expansion amounts of the first bond pad 70 and the second bond pad 71 are filled in the first gap 601 and the second gap 602, thereby implementing equal expansion of the first bond pad 70 and the second bond pad 71. In some embodiments, the second bond pad 72 with a relatively large surface area may be an active bond pad requiring a high current density.

Still referring to FIG. 1 to FIG. 5, in some embodiments, the first dielectric layer 50 has a first thickness, the second dielectric layer 60 has a second thickness, and the first thickness is greater than the second thickness. In some embodiments, the ratio of the first thickness to the second thickness may range from 100-2000. For example, the value range of the first thickness may be within 2 microns-100 nanometers, and the value range of the second thickness may be 5 nanometers-0.5 nanometers.

Still referring to FIG. 3 and FIG. 4, in some embodiments, the size of the first interconnection structure 702 and/or the second interconnection structure 712 is smaller than the size of the first bond pad 70 and the size of the second bond pad 70. The size herein may be a physical quantity such as an extension depth, a width, and a top surface area of the first interconnection structure 702 and/or the second interconnection structure 712.

In the semiconductor structures provided in the foregoing embodiments, a void required for expansion of each bond pad is provided through the second dielectric layer, thereby reducing difficulty in a planarization process of forming the surface recess value of the bond pad. The bond pads may be designed in different sizes. By controlling that bond pads with different surface areas have corresponding depths, it is ensured that the bond pads with the different surface areas can expand at the same height in a temperature increase expansion procedure. Further, a combination of a big bond pad and a small bond pad may be designed, because a bond pad with a larger surface area has a good application prospect in terms of a current density, bonding strength, heat dissipation, and the like. In addition, the semiconductor structure provided in this embodiment of the present disclosure may further reduce a quantity of dummy bond pads and a metal content of a bonding surface. This helps control warping of the semiconductor structure and improve the stability of a bonding process procedure.

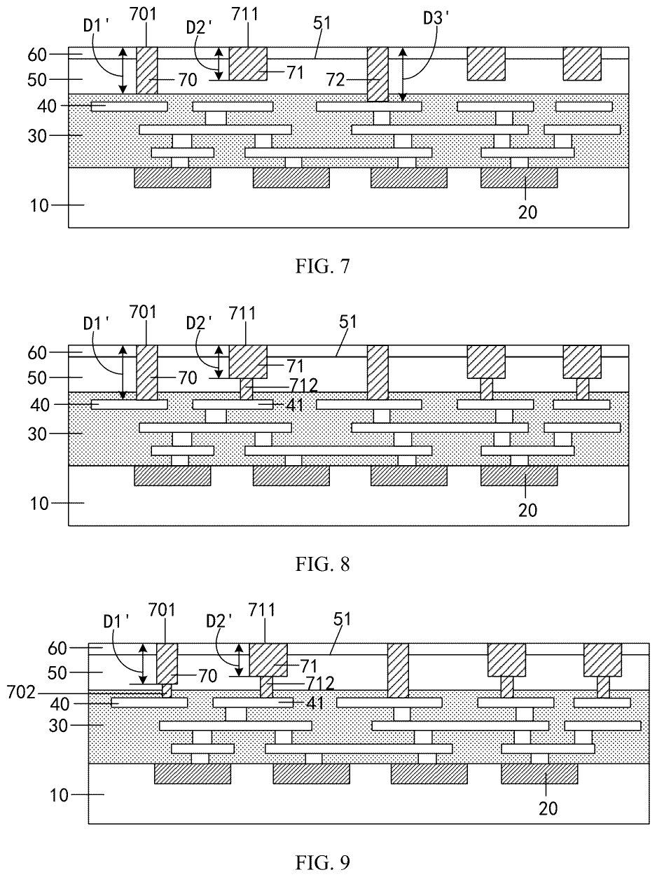

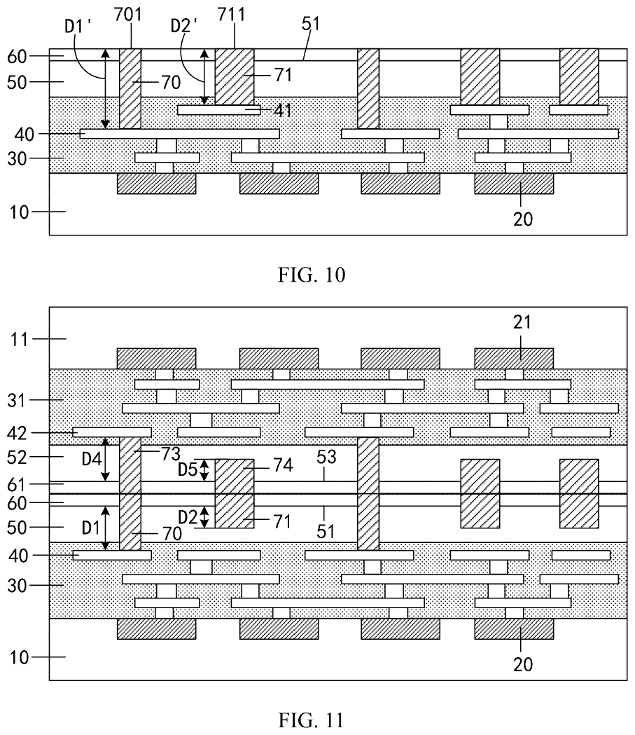

Some embodiments of the present disclosure further provide some other semiconductor structures. Still referring to FIG. 6 to FIG. 10, FIG. 6 to FIG. 10 are schematic cross-sectional views of semiconductor structures according to embodiments of the present disclosure. After the semiconductor structures shown in FIG. 1 to FIG. 5 are formed, bonding processing is performed. In this procedure, the first bond pad 70 and the second bond pad 71 are thermally expanded, to fill the first gap 601 and the second gap 602, and finally separately form the semiconductor structures shown in FIG. 6 to FIG. 10. The semiconductor structure shown in FIG. 1 undergoes bonding processing to form a semiconductor structure shown in FIG. 6, the semiconductor structure shown in FIG. 2 undergoes bonding processing to form a semiconductor structure shown in FIG. 7, the semiconductor structure shown in FIG. 3 undergoes bonding processing to form a semiconductor structure shown in FIG. 8, the semiconductor structure shown in FIG. 4 undergoes bonding processing to form a semiconductor structure shown in FIG. 9, and the semiconductor structure shown in FIG. 5 undergoes bonding processing to form a semiconductor structure shown in FIG. 10. In these semiconductor structures, after being expanded, the first bond pad 70 and the second bond pad 71 separately extend to the second dielectric layer 60. The first bond pad 70 and the second bond pad 71 extend to the same depth in the second dielectric layer 60, so that the top surfaces 701 and 711 of the first bond pad 70 and the second bond pad 71 obtained after expansion are flush with each other. Finally, an extension depth of the first bond pad 70 is D1′, and an extension depth of the second bond pad 71 is D2′. In the semiconductor structure shown in FIG. 7, an active bond pad 72 also extends to the second dielectric layer 60 after expansion, and an extension depth of the active bond pad 72 is D3′.

In some embodiments, the surface area of the top surface 701 of the first bond pad 70 after expansion is less than the surface area of the top surface 711 of the second bond pad 71.

Other parts of the semiconductor structures obtained after bonding processing are the same as those of the semiconductor structures shown in FIG. 1 to FIG. 5 and corresponding embodiments thereof. Details are not described herein again.

Some embodiments of the present disclosure further provide a semiconductor structure. As shown in FIG. 11 to FIG. 13, FIG. 11 to FIG. 13 are schematic cross-sectional views of semiconductor structures according to embodiments of the present disclosure. As shown in FIG. 11, the semiconductor structure includes a first substrate 10 and a second substrate 11. A semiconductor device 20 is disposed in the first substrate 10, an interlayer insulating layer 30 is disposed over the first substrate 10, and a multi-layer metal wiring, including the first conductive layer 40, connected to the semiconductor device 20 is disposed in the interlayer insulating layer 30. A first dielectric layer 50 is disposed on the interlayer insulating layer 30, a second dielectric layer 60 is disposed on the first dielectric layer 50, a first bond pad 70 and a second bond pad 71 extend through a first surface 51 of the first dielectric layer 50 and extend to the second dielectric layer 60, the first bond pad 70 extends to a first depth D1 below the first surface 51 of the first dielectric layer 50, the second bond pad 71 extends to a second depth D2 below the first surface 51 of the first dielectric layer 50, and D2 is less than D1. The first bond pad 70 extends to be electrically connected to the first conductive layer 40, and the second bond pad 71 is not electrically connected to the first conductive layer 40. Extension depths of the first bond pad 70 and the second bond pad 71 in the second dielectric layer 60 are the same, so that the top surfaces of the first bond pad 70 and the second bond pad 71 are flush or substantially flush with the top surface of the second dielectric layer 60. The surface area of the top surface of the first bond pad 70 is less than the surface area of the top surface of the second bond pad 71.

The second substrate 11 includes a semiconductor device 21 disposed therein and an interlayer insulating layer 31 disposed on the second substrate 11. The interlayer insulating layer 31 includes a multi-layer metal wiring, including a conductive layer 42, connected to the semiconductor device 21. A third dielectric layer 52 is disposed on the interlayer insulating layer 31, a fourth dielectric layer 61 is disposed on the third dielectric layer 52, a third bond pad 73 and a fourth bond pad 74 extend through a second surface 53 of the third dielectric layer 52 and extend into the fourth dielectric layer 61, the third bond pad 73 extends to a third depth D4 below the second surface 53 of the third dielectric layer 52, the fourth bond pad 74 extends to a fourth depth D5 below the second surface 53 of the third dielectric layer 52, and D5 is less than D4. The third bond pad 73 extends to be electrically connected to the conductive layer 42, and the fourth bond pad 74 is not electrically connected to the conductive layer 42. Extension depths of the third bond pad 73 and the fourth bond pad 74 in the fourth dielectric layer 61 are the same, so that the top surfaces of the third bond pad 73 and the fourth bond pad 74 are flush or substantially flush with the top surface of the fourth dielectric layer 61. The surface area of the top surface of the third bond pad 73 is less than the surface area of the top surface of the fourth bond pad 74.

The first bond pad 70 is aligned with and bonded to the third bond pad 73, the second bond pad 71 is aligned with and bonded to the fourth bond pad 74, and the second dielectric layer 60 is aligned with and bonded to the fourth dielectric layer 61, to form the semiconductor structure in this embodiment of the present disclosure.

In some embodiments, the semiconductor device 20 and the semiconductor device 21 may be the same semiconductor device, or may be different semiconductor devices. The first substrate 10 and the second substrate 11 may be substrate wafers of the same type or different types.

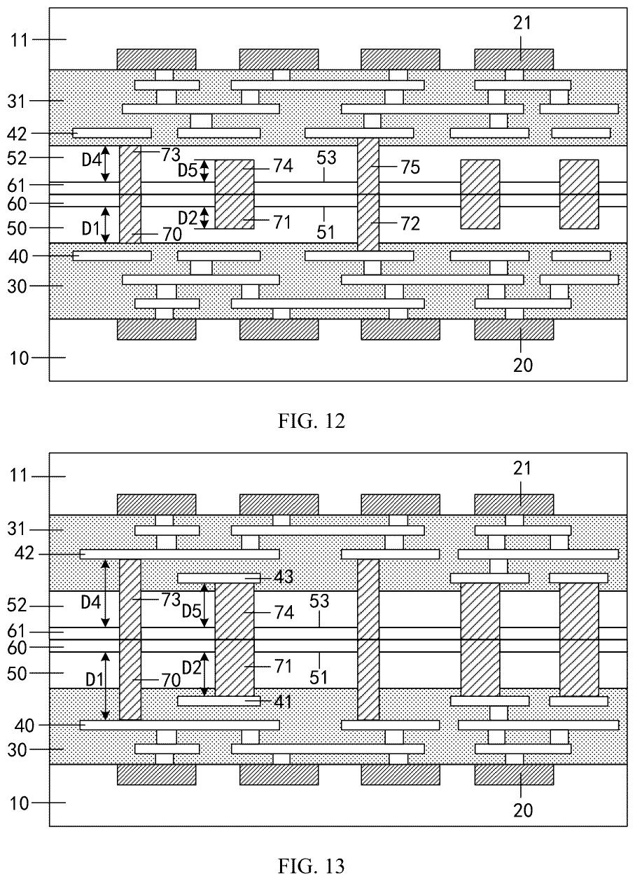

In some embodiments, the first bond pad 70 and the third bond pad 73 may not be electrically connected to the conductive layer, as shown in FIG. 12. Different from FIG. 11, in this case, both the first bond pad 70 and the third bond pad 73 are dummy bond pads. In this case, the first substrate 10 is electrically connected to the second substrate 11 through an active bond pad 72 and an active bond pad 75 bonded to each other.

In some embodiments, the first bond pad 70, the second bond pad 71, the third bond pad 73, and the fourth bond pad 74 are respectively connected to corresponding conductive layers, as shown in FIG. 13. Different from FIG. 12, in this case, the first bond pad 70, the second bond pad 71, the third bond pad 73, and the fourth bond pad 74 are all active bond pads, the first bond pad 70 is connected to a first conductive layer 40, the second bond pad 71 is connected to a second conductive layer 41, the third bond pad 73 is connected to a conductive layer 42, and the fourth bond pad 74 is connected to a conductive layer 43. The conductive layer 42 and the conductive layer 43 may be metal wiring at the same layer, or may be metal wiring at different layers. FIG. 13 shows a case in which the conductive layers are the metal wiring at the different layers.

In the semiconductor structures provided in the foregoing embodiments, each bond pad in the first substrate and the second substrate can implement a good surface bonding effect. In addition, the sizes of the bond pads can be set to be different, thereby improving the flexibility of bond pad design.

In some embodiments, each bond pad in each substrate further has more design forms. For details, refer to FIG. 3 and FIG. 4. A semiconductor structure formed thereby is also included in the present disclosure. Details are not described herein again.

Some embodiments of the present disclosure further provide a manufacturing method for a semiconductor structure, which is described in detail with reference to corresponding accompanying drawings.

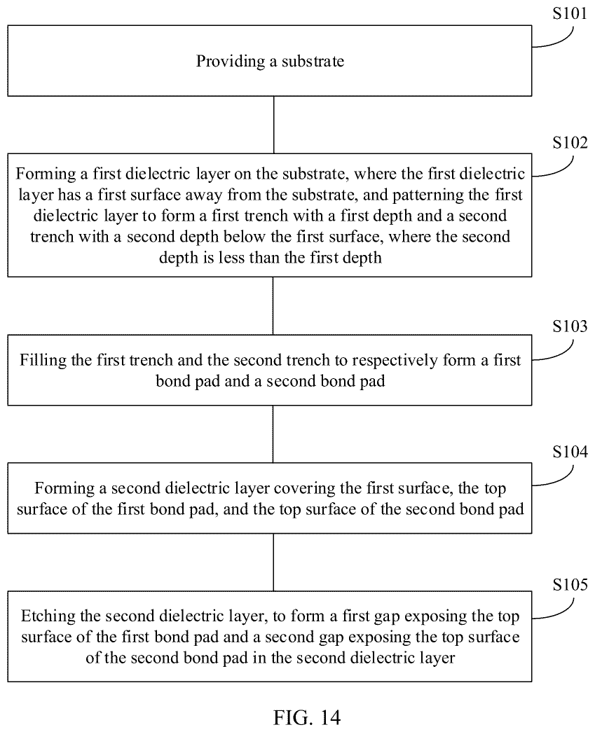

Referring to FIG. 14, FIG. 14 is a flowchart of manufacturing a semiconductor structure. The manufacturing method for a semiconductor structure includes the steps as follows.

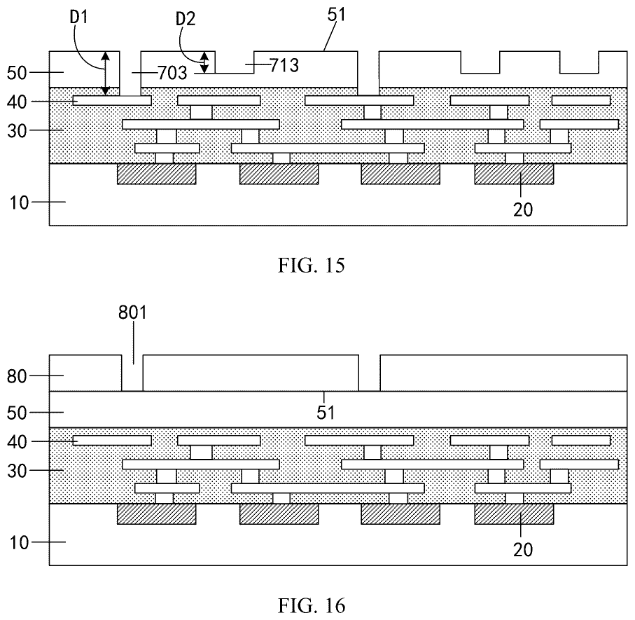

Step S101 is performed: a substrate is provided. As shown in FIG. 15, a substrate 10 is provided. A semiconductor device 20 is disposed in the substrate 10, an interlayer insulating layer 30 is further disposed on the substrate 10, and a multi-layer metal wiring is disposed in the interlayer insulating layer 30, including a first conductive layer 40. The substrate 10 may be a silicon substrate wafer, or may be a substrate wafer having an epitaxial layer, or a silicon on insulator substrate wafer. In some embodiments, the substrate 10 may alternatively be a part of a wafer, e.g., a die or a chip. The semiconductor device 20 may be a CMOS device, a memory device, and/or another passive device. The memory device may include a volatile memory, a non-volatile memory, or the like, and the volatile memory may include, e.g., a DRAM. In some embodiments, when being a DRAM memory device, the semiconductor device 20 may be a memory element including one transistor and one capacitor, or may be a set of multiple memory elements.

Step S102 is performed: a first dielectric layer is formed on the substrate, where the first dielectric layer has a first surface away from the substrate, and the first dielectric layer is patterned to form a first trench with a first depth and a second trench with a second depth below the first surface, where the second depth is less than the first depth. For details, refer to FIG. 15. A first dielectric layer 50 is formed on the substrate 10, and the first dielectric layer 50 covers the interlayer insulating layer 30. The first dielectric layer 50 has a first surface 51 away from the substrate 10, and the first dielectric layer 50 is patterned to separately form a first trench 703 with a first depth D1 and a second trench 713 with a second depth D2 below the first surface 51 of the first dielectric layer 50.

In some embodiments, steps of that the first dielectric layer is patterned to form a first trench with a first depth and a second trench with a second depth below the first surface are shown in FIG. 16 to FIG. 18. FIG. 16 to FIG. 18 are schematic cross-sectional views of semiconductor structures corresponding to corresponding steps of manufacturing the semiconductor structures.

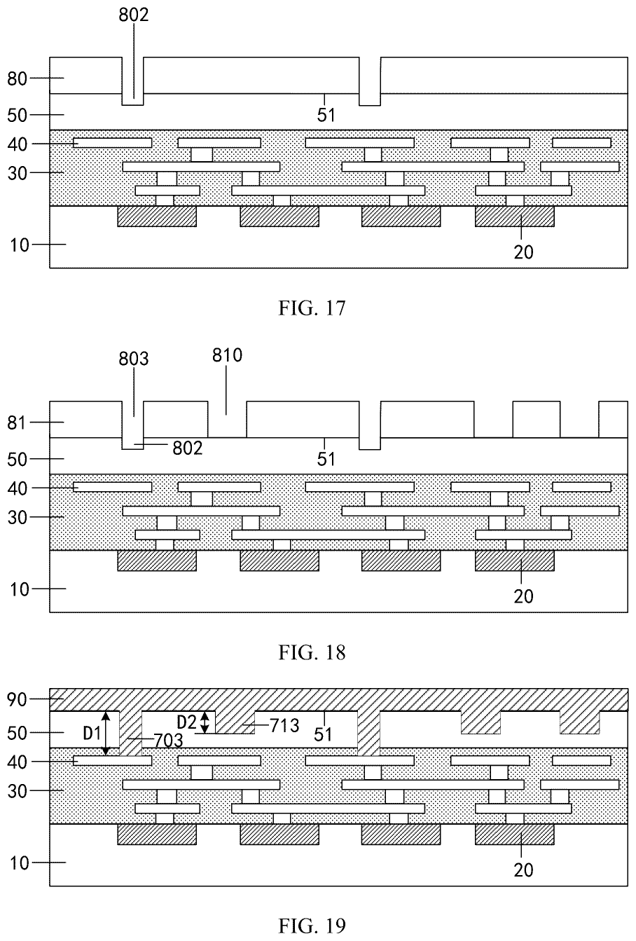

First, referring to FIG. 16, a first mask layer 80 is formed on the first surface 51 of the first dielectric layer 50, the first mask layer 80 is patterned by employing a process such as photolithography and etching to form a first mask pattern 801 in the first mask layer 80, and the first mask pattern 801 exposes the first surface 51 of the first dielectric layer 50. Still referring to FIG. 17, after the first mask pattern 801 is formed, the first dielectric layer 50 is etched downward along the first mask pattern 801 to form a first initial trench 802 below the first surface 51 of the first dielectric layer 50. Still referring to FIG. 18, after the first initial trench 802 is formed, the first mask layer 80 may be first removed, and the first initial trench 802 is retained. Then, a second mask layer 81 is formed on the first surface 51 of the first dielectric layer 50, and the second mask layer 81 is patterned by employing a process such as photolithography and etching to form a second mask pattern 810 in the second mask layer 81. In some embodiments, a third mask pattern 803 is also formed in the second mask layer 81, and the third mask pattern 803 exposes the first initial trench 802. After the second mask pattern 810 and the third mask pattern 803 are formed, etching downward is performed along the second mask layer 81 to finally form the first trench 703 and the second trench 713 as described in FIG. 15.

By performing the foregoing steps, extension depths of the first trench 703 and the second trench 713 and transverse sizes thereof can be more flexibly controlled, to obtain bond pads with different top surface areas.

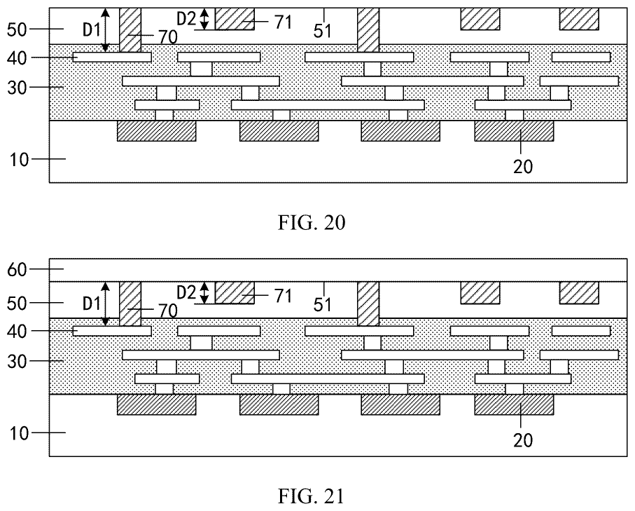

Step S103 is performed: the first trench and the second trench are filled to respectively form a first bond pad and a second bond pad. For details, refer to FIG. 19. After the first trench 703 and the second trench 713 are formed, an initial conductive layer 90 covering the first trench 703 and the second trench 713 is formed on the first surface 51 of the first dielectric layer 50. Next, referring to FIG. 20, after the initial conductive layer 90 is formed, planarization processing is performed on the initial conductive layer 90 to remove the initial conductive layer 90 on the first surface 51 of the first dielectric layer 50 and retain the initial conductive layer 90 located in the first trench 703 and the second trench 713, to finally form a first bond pad 70 and a second bond pad 71. A process for forming the first bond pad 70 and the second bond pad 71 may adopt a damascene process. In this procedure, a surface planarization process, e.g., CMP, is performed, so that the first bond pad 70, the second bond pad 71, and the first surface of the first dielectric layer 50 are finally flush with each other. In this surface planarization processing step, it is unnecessary to control surface recess values of the first bond pad 70 and the second bond pad 71, and it is sufficient to make the surfaces flush with each other, thereby reducing the difficulty of the planarization process.

Step S104 continues to be performed: a second dielectric layer covering the first surface, the top surface of the first bond pad, and the top surface of the second bond pad is formed. For details, refer to FIG. 21. After the first bond pad 70 and the second bond pad 71 are formed, a second dielectric layer 60 is formed on the first surface 51 of the first dielectric layer 50 and on the top surfaces of the first bond pad 70 and the second bond pad 71. The second dielectric layer 60 may be formed by employing a thin film deposition process such as chemical vapor deposition (CVD) and atomic layer deposition (ALD), to obtain a thin film whose thickness is precisely controlled and whose thickness is uniform and compact.

In some embodiments, the first dielectric layer 50 may be SiₓO_{y}, and the second dielectric layer 60 includes an oxide or a nitride, e.g., silicon oxide or silicon nitride (Si₃N₄), silicon carbonitride (SiCN), and silicon oxynitride (SiON). In some embodiments, the first dielectric layer 50 includes SiₓO_{y}, and the second dielectric layer 60 includes SiCN. In some embodiments, the first dielectric layer 50 includes a stacked structure formed by SiₓO_{y} and SiCN, and the second dielectric layer 60 includes SiCN.

Step S105 is performed: the second dielectric layer is etched, to form a first gap exposing the top surface of the first bond pad and a second gap exposing the top surface of the second bond pad in the second dielectric layer. On a basis of the semiconductor structure shown in FIG. 21, to be specific, after the second dielectric layer 60 is formed, a combination process of photolithography, etching, and the like is performed on the second dielectric layer 60, to form the first gap 601 and the second gap 602 in the second dielectric layer 60. A final structure is shown in FIG. 1.

In the manufacturing method for a semiconductor structure shown in the foregoing embodiment, it needs to employ the surface planarization process once when the first bond pad and the second bond pad are formed, to make the surfaces of the first bond pad, the second bond pad, and the first dielectric layer be flush with each other. Then, the thin film deposition process is employed to form a second dielectric layer with a predetermined thickness, and there is no need to employ the surface planarization process to control the second dielectric layer and the surface recess values of the first bond pad and the second bond pad, thereby omitting an expensive and complex surface planarization process step.

In some embodiments, the first trench 703 and the second trench 713 may respectively expose corresponding metal wirings in the interlayer insulating layer 30, and the first bond pad 70 and the second bond pad 71 finally formed are respectively connected to corresponding conductive layers in the multi-layer metal wiring. A final structure is shown in FIG. 5. In some other embodiments, neither the first trench 703 nor the second trench 713 expose corresponding metal wirings in the interlayer insulating layer 30, and neither the first bond pad 70 nor the second bond pad 71 finally formed is connected to corresponding conductive layers in the multi-layer metal wiring. A final structure is shown in FIG. 2.

In some embodiments, before the first dielectric layer is patterned, the first conductive layer and the second conductive layer are further formed in the substrate. For setting of the first conductive layer and the second conductive layer, refer to FIG. 3 and FIG. 4. In this case, when the first trench 703 and the second trench 713 are etched, a first interconnection trench and a second interconnection trench connected to the bottom of the first trench and/or the second trench are formed below the first trench and/or the second trench. The first interconnection trench and the second interconnection trench respectively expose corresponding conductive layers. For example, the first interconnection trench exposes the first conductive layer, and the second interconnection trench exposes the second conductive layer. When the initial conductive layer is subsequently formed, the initial conductive layer is also filled into the first interconnection trench and/or the second interconnection trench. A finally formed structure is shown in FIG. 3 and FIG. 4. The first trench and the first interconnection trench, and the second trench and the second interconnection trench may be formed by employing a dual damascene process.

In some embodiments, after step S105 is performed, the method further includes performing bonding processing, so that the first bond pad fills the first gap and the second bond pad fills the second gap. The semiconductor structures shown in FIG. 6 to FIG. 13 are finally formed after bonding processing is performed.

In a bonding processing procedure, with a temperature increasing procedure, a bonding temperature is usually between 200° C. and 400° C. After initial bonding is implemented at a bonding temperature, to further enhance a mechanical and electrical connection of a bonding interface, a bonding structure is annealed, thereby improving bonding reliability and durability. In these procedures, the first bond pad and the second bond pad are thermally expanded, and expanded parts are filled to the first gap and the second gap, so that a good bonding interface is formed, to further bond to another semiconductor.

A person of ordinary skill in the art may understand that the foregoing implementations are specific embodiments for implementing the present disclosure. In actual application, various modifications may be made to the forms and details of the implementations without departing from the spirit and scope of the embodiments of the present disclosure. Any person skilled in the art may make changes and modifications without departing from the spirit and scope of the embodiments of the present disclosure. Therefore, the protection scope of the embodiments of the present disclosure shall be subject to the scope defined by the claims.

1. A semiconductor structure, comprising:
a substrate;
a first dielectric layer disposed on the substrate, the first dielectric layer having a first surface away from the substrate;
a first bond pad, the first bond pad passing through the first surface and extending to a first depth below the first surface;
a second bond pad, the second bond pad passing through the first surface and extending to a second depth below the first surface, and the second depth being less than the first depth; and
a second dielectric layer, the second dielectric layer being disposed on the first surface, a first gap and a second gap being provided in the second dielectric layer, the first gap exposing a top surface of the first bond pad, and the second gap exposing a top surface of the second bond pad.

2. The semiconductor structure according to claim 1, wherein the top surface of the first bond pad and the top surface of the second bond pad are flush with the first surface.

3. The semiconductor structure according to claim 1, wherein a surface area of the top surface of the first bond pad exposed to the first gap is less than a surface area of the top surface of the second bond pad exposed to the second gap.

4. The semiconductor structure according to claim 1, wherein the first dielectric layer has a first thickness, the second dielectric layer has a second thickness, and the first thickness is greater than the second thickness.

5. The semiconductor structure according to claim 1, further comprising a first conductive layer and a second conductive layer disposed in the substrate, wherein the first conductive layer is connected to a bottom surface of the first bond pad and the second conductive layer is connected to a bottom surface of the second bond pad.

6. The semiconductor structure according to claim 5, further comprising a first interconnection structure and a second interconnection structure disposed in the first dielectric layer, wherein the bottom surface of the first bond pad is connected to the first conductive layer through the first interconnection structure, and the bottom surface of the second bond pad is connected to the second conductive layer through the second interconnection structure.

7. The semiconductor structure according to claim 5, wherein a top surface of the first conductive layer and a top surface of the second conductive layer are at different horizontal planes.

8. A semiconductor structure, comprising:
a substrate;
a first dielectric layer disposed on the substrate, the first dielectric layer having a first surface away from the substrate;
a first bond pad, the first bond pad passing through the first surface and extending to a first depth below the first surface;
a second bond pad, the second bond pad passing through the first surface and extending to a second depth below the first surface, and the second depth being less than the first depth; and
a second dielectric layer, the second dielectric layer being disposed on the first surface, the first bond pad and the second bond pad further extending to the second dielectric layer separately, and extension depths of the first bond pad and the second bond pad in the second dielectric layer being the same.

9. The semiconductor structure according to claim 8, wherein a top surface of the first bond pad and a top surface of the second bond pad are exposed to a top surface of the second dielectric layer, and a surface area of the top surface of the first bond pad is less than a surface area of the top surface of the second bond pad.

10. The semiconductor structure according to claim 9, wherein the top surface of the first bond pad is flush with the top surface of the second bond pad.

11. The semiconductor structure according to claim 8, further comprising a first conductive layer and a second conductive layer disposed in the substrate, wherein the first conductive layer is connected to a bottom surface of the first bond pad and the second conductive layer is connected to a bottom surface of the second bond pad.

12. A manufacturing method for a semiconductor structure, comprising:
providing a substrate;
forming a first dielectric layer on the substrate, the first dielectric layer having a first surface away from the substrate, and patterning the first dielectric layer to form a first trench with a first depth and a second trench with a second depth below the first surface, the second depth being less than the first depth;
filling the first trench and the second trench to respectively form a first bond pad and a second bond pad;
forming a second dielectric layer covering the first surface, a top surface of the first bond pad, and a top surface of the second bond pad; and
etching the second dielectric layer, to form a first gap exposing the top surface of the first bond pad and a second gap exposing the top surface of the second bond pad in the second dielectric layer.

13. The manufacturing method according to claim 12, wherein steps of the patterning the first dielectric layer to form a first trench with a first depth and a second trench with a second depth below the first surface comprise:
forming a first mask layer on the first surface, patterning the first mask layer to form a first mask pattern in the first mask layer, and performing etching downward along the first mask pattern to form a first initial trench below the first surface; and
forming a second mask layer on the first dielectric layer, patterning the second mask layer to form a second mask pattern in the second mask layer, and etching the first dielectric layer along the second mask pattern and the first initial trench to respectively form the second trench and the first trench in the first dielectric layer.

14. The manufacturing method according to claim 13, wherein steps of the filling the first trench and the second trench to respectively form a first bond pad and a second bond pad comprise:
forming an initial conductive layer covering the first trench and the second trench, wherein the initial conductive layer also covers the first surface; and
planarizing the initial conductive layer to respectively form, in the first trench and the second trench, the first bond pad and the second bond pad that are flush with the first surface, wherein an area of the top surface of the first bond pad exposed to the first gap is less than an area of the top surface of the second bond pad exposed to the second gap.

15. The manufacturing method according to claim 12, wherein a first conductive layer and a second conductive layer are formed in the substrate before the first dielectric layer is patterned, and a bottom of the first trench exposes the first conductive layer and a bottom of the second trench exposes the second conductive layer when the first dielectric layer is etched to form the first trench and the second trench.

16. The manufacturing method according to claim 12, wherein a first conductive layer and a second conductive layer are formed in the substrate before the first dielectric layer is patterned, a first interconnection trench and a second interconnection trench are further formed when the first dielectric layer is etched to form the first trench and the second trench, a top of the first interconnection trench is connected to a bottom of the first trench, a bottom of the first interconnection trench exposes the first conductive layer, a top of the second interconnection trench is connected to a bottom of the second trench, and a bottom of the second interconnection trench exposes the second conductive layer.

17. The manufacturing method according to claim 12, wherein bonding processing is performed after the first gap and the second gap are formed, so that the first bond pad fills the first gap and the second bond pad fills the second gap.

18. The semiconductor structure according to claim 1, wherein the first gap completely exposes an entire upper surface of the first bonding pad, and the second gap completely exposes the entire upper surface of the second bonding pad.

19. The semiconductor structure according to claim 11, the first conductive layer and the second conductive layer are metal wiring at different layers, top surfaces of the first conductive layer and the second conductive layer are located at different horizontal planes.

20. The manufacturing method according to claim 12, wherein the top surface of the first bond pad is flush with the top surface of the second bond pad.
